(19) United States
(12) Patent Application Publication
(10) Pub. No.: US 2008/0258264 A1
(43) Pub. Date: Oct. 23, 2008

(54) SEMICONDUCTOR DEVICE AND METHOD FOR MANUFACTURING THE SAME

(76) Inventors: Yoshiki Kamata, Tokyo (JP); Akira Nishiyama, Yokohama-shi (JP); Tsunehiro Ino, Fujisawa-shi (JP); Yuuichi Kamimuta, Yokohama-shi (JP); Masahiro Koike, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/137,929

(22) Filed: Jun. 12, 2008

Related U.S. Application Data
(63) Continuation of application No. 11/011,044, filed on Dec. 15, 2004.

(30) Foreign Application Priority Data
Dec. 25, 2003 (JP) 2003-431028

(51) Int. Cl. H01L 29/20; H01L 21/469

(52) U.S. Cl. 257/615; 438/785; 257/E21.108

(57) ABSTRACT

Disclosed is a semiconductor device comprising a Ge semiconductor area, and an insulating film area, formed in direct contact with the Ge semiconductor area, containing metal, germanium, and oxygen.

### CROSS-REFERENCE TO RELATED APPLICATIONS

The present continuation application claims the benefit of priority under 35 U.S.C. § 120 to application Ser. No. 11/011,044, filed on Dec. 15, 2004, and under 35 U.S.C. § 119 from Japanese Application No. 2003-431028, filed on Dec. 25, 2003, the entire contents of both are incorporated herein by reference.

### BACKGROUND OF THE INVENTION

1. Field of the Invention

The present invention relates to a semiconductor device and a method for manufacturing the semiconductor device.

2. Description of the Related Art

Silicon single-crystal substrates are conventionally used in semiconductor devices. However, much attention is being paid to germanium substrates because in these substrates, electrons and holes have a larger mobility than in silicon substrates. On the other hand, gate insulating films in transistors are shifting from conventional thermal oxide films to deposited films containing high dielectric materials in order to reduce effective oxide thickness (EOT). Thus, various methods have been proposed to form a stable high-dielectric gate insulating film on a germanium substrate. With these methods, a crystal HfO₂ gate insulating film is formed on the substrate via an interface layer.

Further, a technique has been disclosed which makes an amorphous high-dielectric insulating film containing Hf when the film is formed on a Ge or Si substrate, in order to reduce leakage current. However, there is a tradeoff between a large dielectric constant and the control of leakage with the amorphous film. Further, this disclosure does not indicate whether or not an interface layer is present.

In general, the presence of an interface layer of a small dielectric constant causes high electric fields to be applied to the interface layer to reduce effective electric fields applied to the film. This in turn reduces the coupling ratio of a floating electrode to a control electrode. Thus, preferably, no interface layer is present. In particular, for a flash memory, a crystallized insulating film increases the leakage current, varies the performance of elements, and reduces the reliability of the elements. Thus, the crystalinity of the insulating film has larger adverse effects than the presence of an interface layer. At present, semiconductor devices are not sufficiently reliable for a transistor or flash memory having a high-dielectric insulating film.

### BRIEF SUMMARY OF THE INVENTION

According to one aspect of the present invention, there is provided a semiconductor device comprising a Ge semiconductor area; and an insulating film area formed in direct contact with the Ge semiconductor area and containing metal, germanium, and oxygen.

According to one aspect of the present invention, there is provided a semiconductor device comprising a substrate, a tunnel oxide layer formed on the substrate, a stacked gate comprising a floating gate and a control gate, and an insulating film sandwiched between the floating gate and the control gate, wherein at least one of the floating gate and the control gate has a Ge semiconductor area in contact with the interpoly insulating film and the interpoly insulating film consists of an amorphous insulating film area containing metal, germanium, and oxygen.

According to one aspect of the present invention, there is provided a method for manufacturing a semiconductor device comprising forming an insulating film area containing metal, germanium, and oxygen, on a Ge semiconductor area; and thermally treating the insulating film area to reduce a film thickness of a part of the insulating film area to at most 0.5 nm, the part being located between the insulating film area and the Ge semiconductor area and having a content of the metal smaller than a bulk concentration in the insulating film area.

According to another aspect of the present invention, there is provided a method for manufacturing a semiconductor device comprising contacting an insulating film area containing metal and oxygen, with a Ge semiconductor area; and thermally treating the insulating film area to reduce a film thickness of a part of the insulating film area to at most 0.5 nm, the part being located between the insulating film area and the Ge semiconductor area and having a metal content smaller than a bulk concentration in the insulating film area.

### BRIEF DESCRIPTION OF THE SEVERAL VIEWS OF THE DRAWING

FIG. 1 is a sectional TEM photographic view of ZrO₂ on a Ge substrate (before thermal treatment);

FIG. 2 is a sectional TEM photographic view of ZrGeO on the Ge substrate (after thermal treatment);

FIG. 3 is a sectional view schematically illustrating the Ge substrate and ZrGeO film in FIG. 2;

FIG. 4 is a sectional TEM photographic view of ZrO₂ on an Si substrate (before thermal treatment);

FIG. 5 is a sectional TEM photographic view of the ZrO₂ on the Si substrate (after thermal treatment);

FIG. 6 is a sectional view schematically illustrating the Si substrate and ZrO₂ film in FIG. 5;

FIG. 7 is a graph showing conditions under which a ZrGeO film is amorphous;

FIG. 8 is a graph showing conditions under which an HfGeO film is amorphous;

FIG. 9 is a sectional TEM photographic view of ZrO₂ on a Ge substrate (before thermal treatment);

FIG. 10 is a sectional TEM photographic view of the ZrO₂ on the Ge substrate (after thermal treatment);

FIG. 11 is a sectional view of a MISFET according to an embodiment of the present invention;

FIG. 12 is a sectional view of a flash memory according to an embodiment of the present invention;

FIG. 13 is a sectional TEM photographic view of a ZrGeO film formed on a Ge substrate; and

FIG. 14 is a Ge 3d spectrum of a ZrO₂ film.

### DETAILED DESCRIPTION OF THE INVENTION

Embodiments of the present invention will be described below.

The present inventors have concentrated their energy on the examination of formation of a high-dielectric insulating film on a Ge substrate to obtain the knowledge described below. When the conventional technique is used to form a gate insulating film consisting of a high-dielectric material such as an HfO₂ film, on a Ge substrate, an interface layer mainly comprising Ge oxide is formed between the substrate and the insulating film. The presence of such an interface layer impairs the effect of the Ge substrate which increases the mobility of electrons and holes above that of a silicon substrate. Accordingly, the high-dielectric insulating film is desirably formed directly in contact with the Ge substrate without providing any interface layer. If the content of metal (Zr, Hf, or the like) contained in the high-dielectric insulating film increases sharply in the interface between the Ge substrate and the high-dielectric insulating film, the high-dielectric insulating film is considered to be formed directly in contact with the Ge substrate. Specifically, if in the interface between the Ge substrate and the high-dielectric insulating film, the content of the metal reaches a bulk concentration at a distance of at most 0.5 nm from a surface of the Ge substrate, it can be determined that no interface layer is substantially present between the Ge substrate and the high-dielectric insulating film.

The present inventors pay attention to the fact that the above interface layer is mainly formed of GeOₓ (x is 0 to 2) and that GeOₓ is thermally unstable.

The present inventors have thus executed a thermal operation to enable the interface layer to be eliminated. The interface layer can be eliminated using, for example, techniques described below.

(1) Ge is introduced when a high-dielectric film is formed on a Ge semiconductor area.

(2) Ge layer or an insulating film containing Ge is formed on a Ge semiconductor area. Then, a high-dielectric film is formed and a thermal operation is executed to form a germanate containing a high dielectric film.

(3) A high-dielectric film is formed on a Ge semiconductor area. Then, Ge layer or an insulating film containing Ge is formed and a thermal operation is executed to form a germanate containing a high-dielectric film.

(4) A high dielectric film is formed on a Ge semiconductor area. Then, Ge ions are injected and mixed into the film.

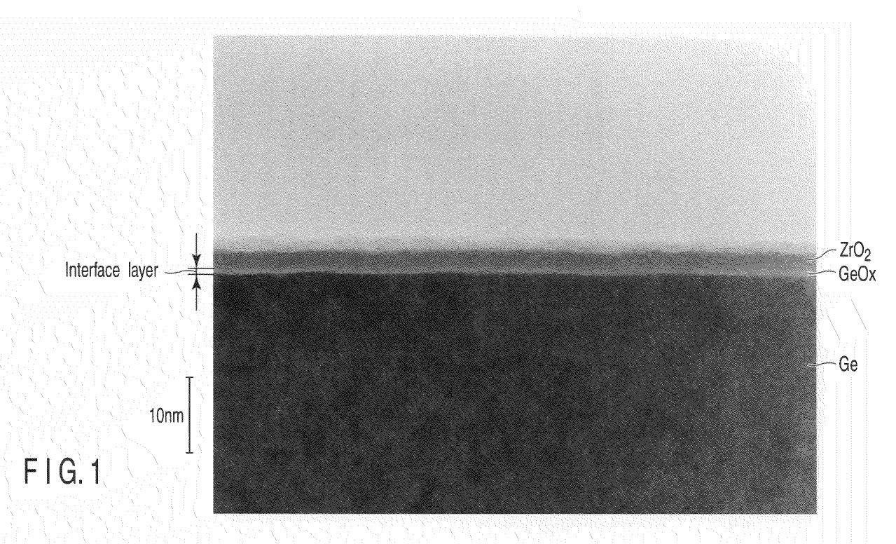

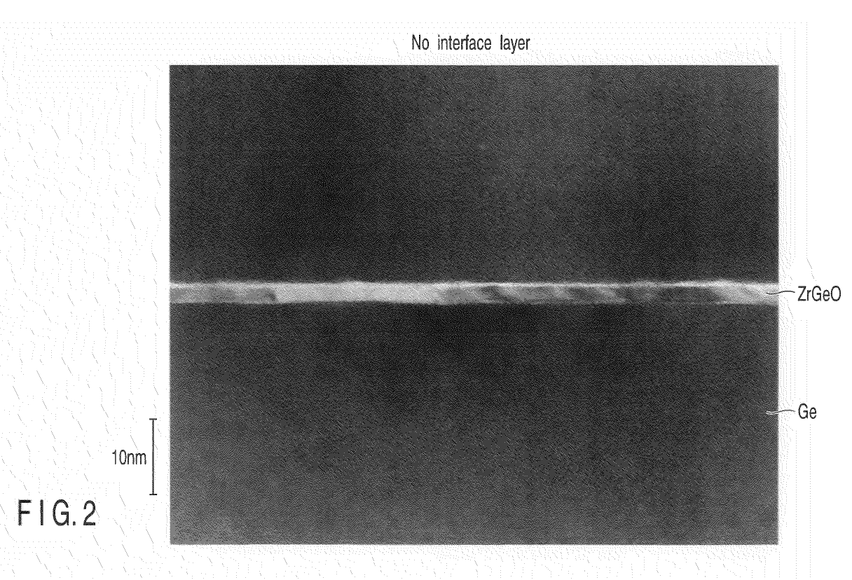

FIGS. 1 and 2 show transmission electron microscopic TEM photographs of a cross section of a ZrO₂ film formed on a Ge substrate by sputtering, immediately after deposition and after a thermal treatment, respectively. The thermal treatment was carried out in a nitrogen atmosphere at 600° C. for about 30 minutes.

As shown in the photograph in FIG. 1, the ZrO₂ film is amorphous immediately after deposition. An interface layer of film thickness about 0.6 nm is present between the ZrO₂ film and the Ge substrate. The interface layer contains Ge oxide, which is incorporated into the ZrO₂ film during a thermal treatment to form a ZrGeO film. As a result, the interface layer disappears as shown in the photograph in FIG. 2. The TEM observation confirms that the ZrGeO film formed is crystallized.

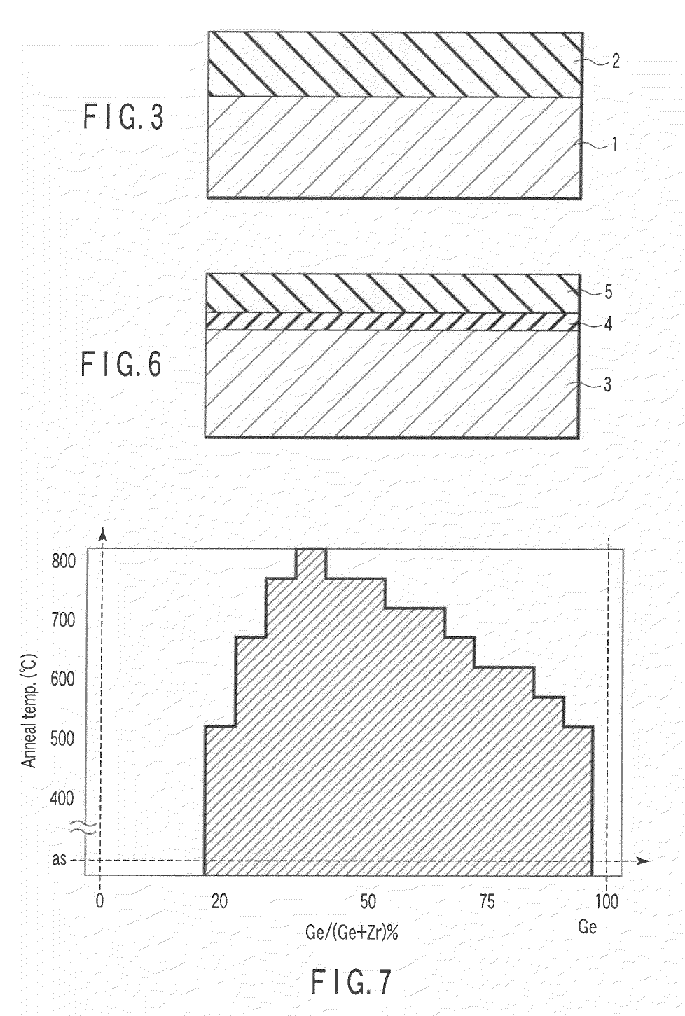

The sectional view in FIG. 3 schematically shows the Ge substrate and ZrGeO film in FIG. 2. As shown in the figure, a crystallized ZrGeO film 2 is formed directly on a Ge substrate 1.

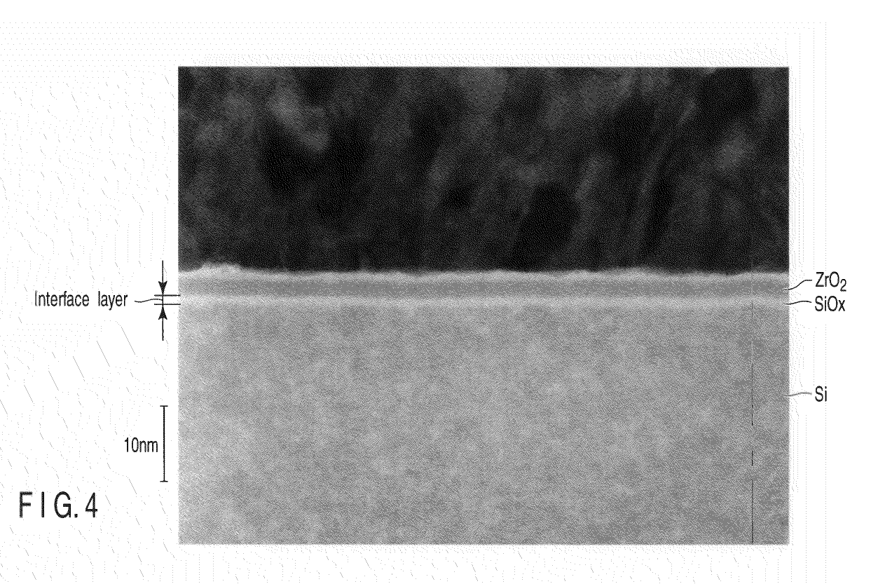

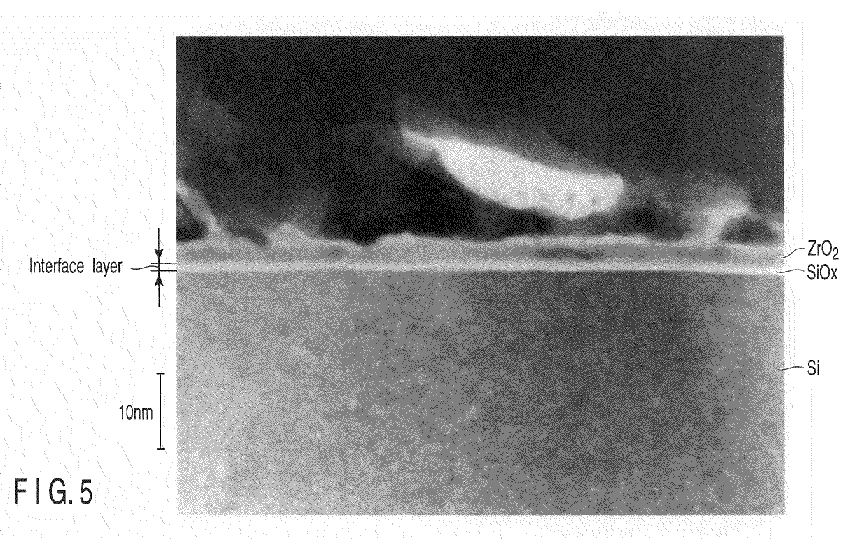

For reference, FIGS. 4 and 5 show TEM images of a ZrO₂ film formed on an Si substrate by sputtering, immediately after deposition and after a thermal treatment, respectively. As shown in these photographs, an interface layer is present between the Si substrate and the ZrO₂ film both before and after the thermal treatment. The ZrO₂ film is confirmed to be crystallized after the thermal treatment.

The sectional view in FIG. 6 schematically shows the Si substrate and ZrO₂ film in FIG. 5. As shown in the figure, a crystallized ZrO₂ film 5 is formed on an Si substrate 3 via an interface layer 4.

In this manner, an insulating film containing a high-dielectric material is crystallized during a thermal treatment process. For example, a ZrO₂ film is crystallized at about 400° C., and a silicate film such as a ZrSiO film is subjected to phase separation and crystallization at about 400 to 1,000° C. When the insulating film is crystallized to have grain boundaries formed inside, the element becomes less reliable. Further, it is difficult to realize a perfect crystal free from grain boundaries or defects. Therefore, the gate insulating film is preferably amorphous.

The present inventors have found that there is an optimum condition to suppress the crystallization of a high-dielectric insulating film containing Ge to make it amorphous. The condition is the combination of a thermal treatment temperature and the content of Ge in all positive ions contained in the high dielectric insulating film (for example, Ge/(Ge+Zr) or Ge/(Ge+Hf)).

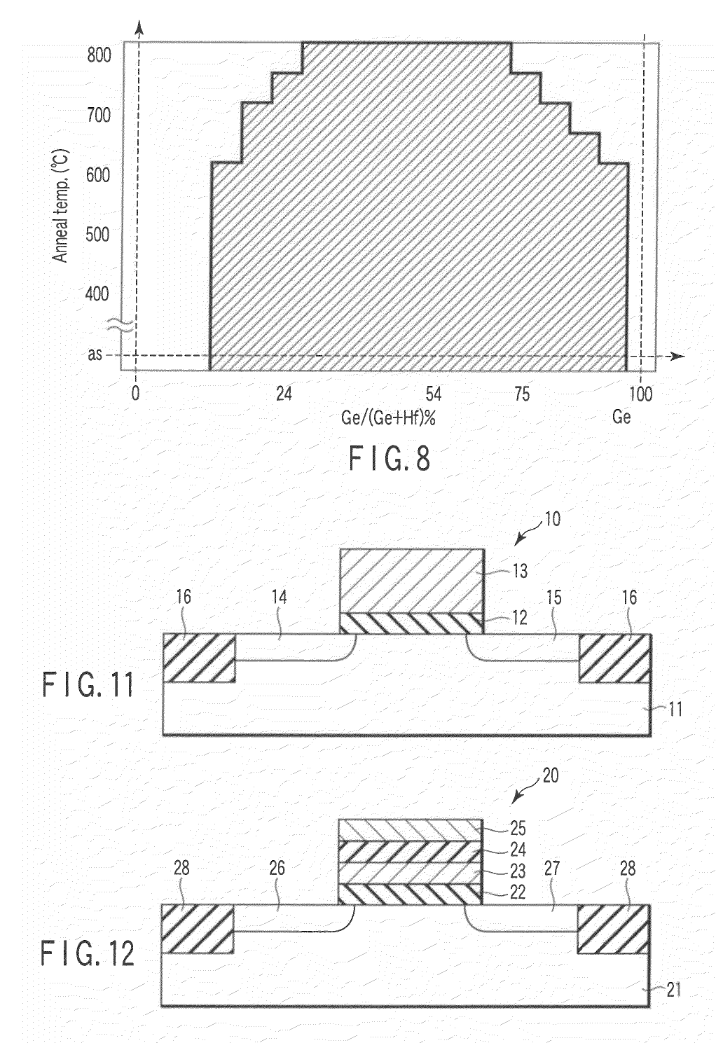

The graphs in FIGS. 7 and 8 show crystallization suppression conditions for the ZrGeO film and HfGeO film. Films as samples were formed by forming a ZrGeO film or HfGeO film containing a predetermined amount of Ge on a substrate by sputtering and thermally treating the film at a predetermined temperature. The ordinate indicates the maximum thermal temperature applied to the high-dielectric insulating film during a thermal operation such as an impurity activating process or a contact metal process (for example, a source/drain silicide process). In each graph, a shaded part indicates an area in which an amorphous film is obtained. However, even in an area outside the shaded part, an amorphous film can be obtained by changing an input wattage or the geometrical arrangement of a sputter target and the substrate. For example, a ZrO₂ as-sputter sample in FIG. 1 is amorphous. In this case, as shown in the photograph in FIG. 1, an interface layer of film thickness about 0.5 to 0.7 nm is present between the Ge substrate and the insulating film.

FIG. 7 indicates that the crystallinity of the film varies depending on the content of Ge in the film and the thermal treatment temperature. The presence of a certain amount of Ge in the film improves heat resistance to suppress the crystallization of ZrO₂. However, an excessive amount of Ge causes GeO₂ crystals to be precipitated. When the content of Ge in the film is within the range shown in FIG. 7, the crystallization of the film can be suppressed. Consequently, even after a thermal operation at the temperatures shown on the ordinate in the figure, the amorphous state can be maintained.

FIG. 7 shows that with a fixed Ge content, the likelihood of crystallization increases consistently with the thermal treatment temperature and that the crystallization temperature depends on the Ge content. This is because in the system shown in FIG. 1, the content of Ge in the film is expected to be about 15 to 20% on the basis of the relative ratio of the interface layer to the ZrO₂ film in terms of TEM film thickness, so that the ZrO₂ remains amorphous until 400° C. but is crystallized at 500° C. or higher.

Further, as shown in FIG. 8, the HfGeO film exhibits a similar tendency.

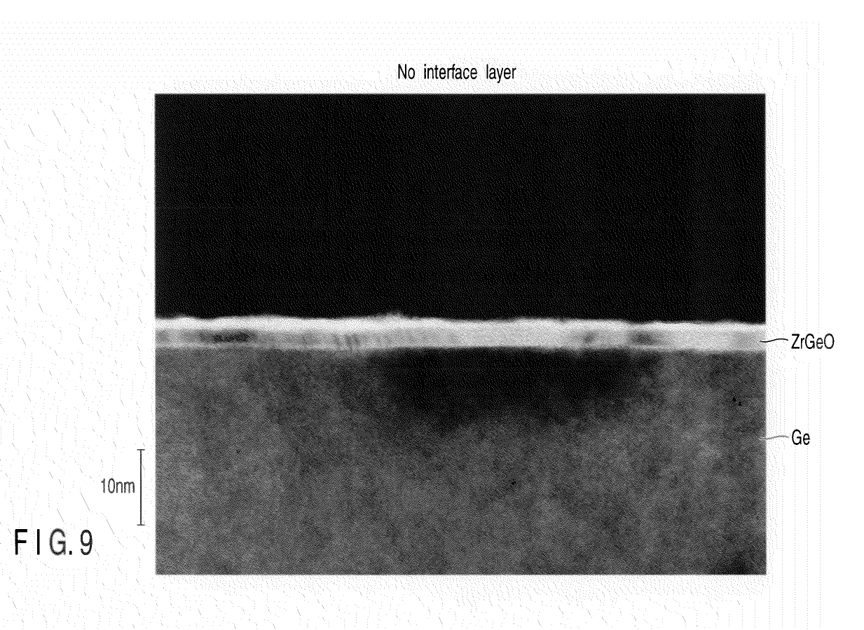

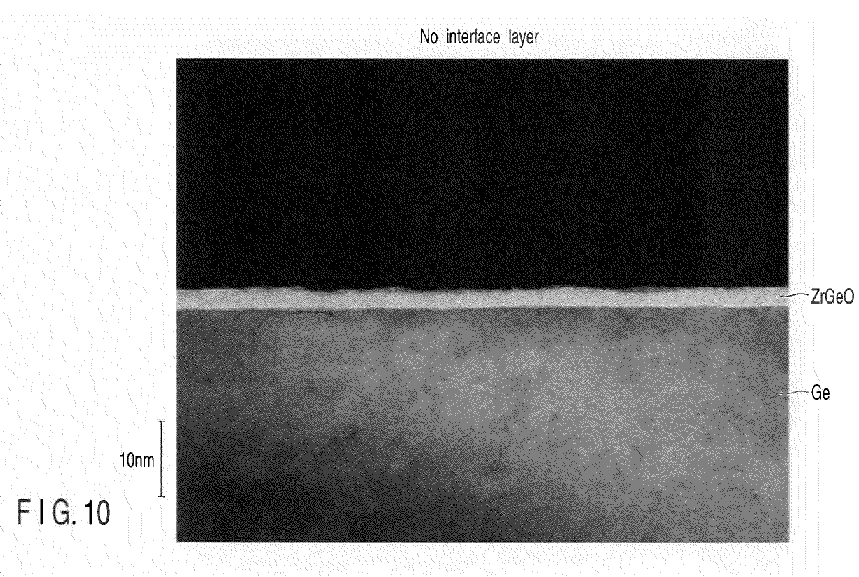

FIGS. 9 and 10 show TEM images of a ZrO₂ film formed on a Ge substrate by a sputtering process, after thermal treatments at 500 and 400° C., respectively. As shown in the photograph in FIG. 9, a sample thermally treated at 500° C. is crystallized in spite of the absence of an interface layer as in the case of a thermal treatment at 600° C. (FIG. 2). In contrast, with a thermal treatment at 400° C., no interface layer is present and the sample is amorphous as show in the photograph in FIG. 10. These results indicate that the thermal treatment of at least 400° C. is sufficient to eliminate the interface layer. The difference in crystallinity between the 400° C. sample and both 500° C. and 600° C. samples can be understood from FIG. 7.

A semiconductor device according to an embodiment of the present invention is, for example, a MISFET such as the one shown in FIG. 11. In the illustrated semiconductor device, a gate electrode 13 is placed, via a gate insulating film 12, in an element area in a substrate 11 in which an element isolation insulating film 16 is formed. A source area 14 and a drain area 15 each consisting of a high-concentration impurity diffusion area is formed between the gate insulating film 12 and the substrate 11. These components constitute MIS transistor 10. A source/drain area may be formed in an area other than the high-concentration impurity area by a Schottky junction consisting of metal or a compound of a substrate and metal.

The substrate 11 corresponds to a germanium semiconductor area and may be formed of Ge or SiₓGe_{1-c} (x is 0 to 1). The substrate may contain an appropriate amount of C and may be a substrate on an insulator, for example, a Ge on insulator (GOI). The gate insulating film 12 is formed of a high-dielectric insulating film containing Ge as already described. The gate insulating film 12 is formed on the substrate 11 without any interface layer so as to contact directly with the substrate 11. The gate insulating film 12 is preferably amorphous so as to reduce a leakage current.

The MIS transistor 10 may be manufactured by a conventional method or a replacement type method. With the conventional method, after the gate insulating film 12 and the gate electrode 13, a source area 14 and a drain area 15 are formed. In contrast, with the replacement type method, after the gate insulating film 12, a dummy gate electrode and then a source/drain area are formed. Then, the dummy gate is removed and a gate electrode 13 is formed. The electrode used for the replacement type method is often made of metal, so that this method is sometimes called a metal gate process. With the replacement type method, the gate insulating film also varies before and after the formation of a source/drain area.

The semiconductor device according to the embodiment of the present embodiment may be a flash memory such as the one shown in FIG. 12. In the illustrated semiconductor device, a tunnel oxide film 22, a floating gate 23, an interpoly insulating film 24, and a control gate 25 are sequentially formed in the element area of the substrate 21 in which the element isolation insulating film 28 is formed. A source area 26 and a drain area 27 each consisting of a high-concentration impurity diffusion area is formed between the tunnel oxide film 22 and the substrate 21. These components constitute a flash memory 20.

The substrate 21 may be formed of Si, SiₓGe₁₋ₓ (x is 0 to 1), or Ge. The substrate may contain an appropriate amount of C and may be a substrate on an insulator, for example, Si-on-insulator (SOI).

The interpoly insulating film 24 is formed of an amorphous high-dielectric insulating film containing Ge as described above. At least one of the floating gate 23 and control gate 25 has a Ge semiconductor area on its side closer to the interpoly insulating film 24. Preferably, no interface layer is present between the Ge semiconductor area and the interpoly insulating film 24.

ZrO₂, HfO₂, or other high-dielectric materials may be used to construct the gate insulating film 12 in the MISFET 10 or the interpoly insulating film 24 in the flash memory 20. The high-dielectric insulating film may include, for example, Al, Ba, Ce, Gd, Hf, La, Mg, Pb, Pr, Sc, St, Ta, Ti, Y, or Zr, or their oxide or oxynitride. Specifically, it may be possible to use an AlGeO film, an HfGeO film, a ZrGeO film, a TiGeO film, an HfAlGeO film, a ZrAlGeO film, a TiAlGeO film, an HfZrGeO film, a TiZrGeO film, an HfTiGeO film, an AlGeON film, an HfGeON film, a ZrGeON film, a TiGeON film, an HfAlGeON film, a ZrAlGeON film, a TiAlGeON film, an HfZrGeON film, a TiZrGeON film, or an HfTiGeON film. Moreover, Ge may be contained in an oxide of a perovskite structure such as BaStTiO₃ (BST), PbZrTiO₃ (PZT), or StTiO₃ (STO).

The high-dielectric insulating film containing Ge can be formed by, for example, a sputtering process. A predetermined target may be used to deposit a ZrGeO film with a desired Ge content directly on a substrate or Ge ions may be injected after a ZrO₂ film has been formed by the sputtering process. Alternatively, a ZrO₂ film and a GeO₂ film may be stacked by the sputtering process. In this case, a ZrGeO film is formed by heating the stacked film obtained to sufficiently mix the two films together.

Alternatively, a common film formation process may be used such as another physical film formation process, for example, evaporation of laser ablation, a chemical film formation process, for example, a chemical vapor deposition (CVD) process, or an atomic layer deposition (ALD) process.

With the CVD, a film can be formed by a bubbling process using a liquid source of Zr oxide such as tetra-t-butoxyzirconium (Zr(O-t-C₄H₉)₄) or a liquid source of Ge oxide such as tetramethoxygermanium (Ge(OCH₃)₄) or tetraethoxygermanium (Ge(OC₂H₅)₄. A gas source such as GeH₄ or GeCl₄ may be used for the Ge oxide.

With the ALD, ZrO₂ and GeO₂ are alternately deposited. For example, first, GeO₂ layer is deposited in one atomic layer on a Ge substrate, and then ZrO₂ layer is deposited in one atomic layer on the GeO₂ layer (the order may be changed so that the deposition of ZrO₂ is followed by the deposition of GeO₂). Moreover, the substrate is heated to sufficiently mix the two layers together. For example, X-ray photoelectron spectroscopy (hereinafter referred to as XPS) can be used to check how well the two layers are mixed together. Before heating, O 1 s peaks are observed as two peaks attributed to Zr—O—Zr and Ge—O—Ge, respectively. After heating, an O 1 s peak is observed as one wide peak attributed to the statistical distribution of Zr—O—Zr, Ge—O—Ge, and Zr—O—Ge. This makes it possible to confirm that the two layers have been sufficiently mixed together.

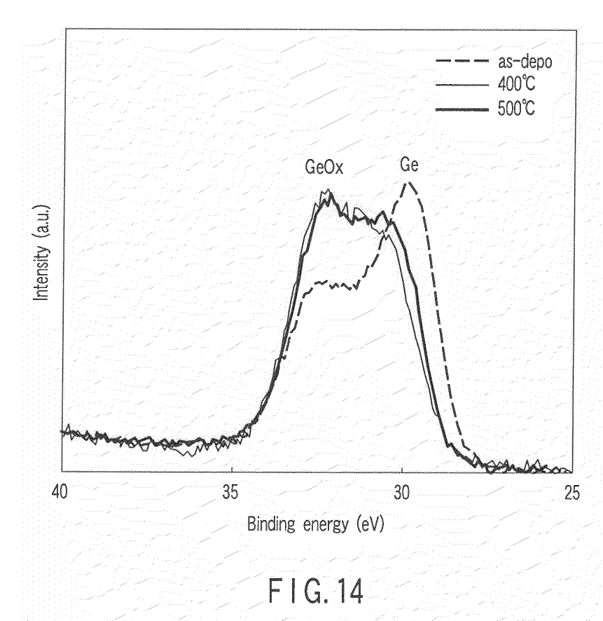

Further, it is possible to check whether or not Ge has been incorporated into the film on the basis of a variation in peak intensity of Ge oxide present near a surface of the ZrO₂ film. For example, FIG. 1 shows that about 3-nm part of the ZrO₂ on the Ge substrate is formed into an interface layer immediately after the sputter film formation. A result of XPS measurement of a Ge 3d spectrum from this film corresponds to an as-depo spectrum shown in FIG. 14. The angle between the surface of the sample and a detector (take-off angle, TOA) is set at 15° so as to be sensitive to information on the vicinity of the surface of the film. An X ray source is an Al Kα ray.

Under these measurement conditions, the peak of the as-depo sample consists of a peak resulting from the Ge—Ge bonds in the substrate and an oxide peak resulting from an interface GeOₓ (x is 0 to 2). A nitrogen atmosphere thermal treatment was applied to the sample at 400 and 500° C. for about 30 minutes. In this case, the respective results of XPS measurement of the Ge 3d spectrum correspond to 400° C. and 500° C. in FIG. 14, respectively. The spectra have been normalized in terms of area. The figure indicates that in the 400° C. and 500° C. samples, the peak of the Ge oxide in the film increases compared to the as-depo sample. The combination of these results with TEM images corresponding to the respective samples indicates that these thermal operation has allowed Ge to be sufficiently incorporated into the film.

A ZrGeO film of a desired film thickness can be formed by appropriately repeating a process of alternately depositing ZrO₂ and GeO₂ and heating and mixing these layers together. The thermal operation need not necessarily be executed during each process but may be executed after ZrO₂ and GeO₂ have been alternately deposited a number of times.

Immediately after a ZrGeO film has been deposited on the Ge substrate, an interface layer is formed between the ZrGeO film and the substrate. The interface layer can be eliminated by thermal treatment. Preferably, the interface in the substrate is thermally treated with a surface of the ZrGeO film covered so as not to be exposed to an oxidation atmosphere. This is because the disappearance of the interface layer is facilitated. This can be accomplished by forming an electrode made of, for example, Pt on a ZrGeO film by electron evaporation. Alternatively, a thermal treating dummy electrode may be used which consists of metal, a semiconductor, an insulating film, or the like.

The high-dielectric insulating film containing Ge preferably contains nitrogen. This further suppresses the crystallization of the film to facilitate the formation of an amorphous film. An excessive amount of nitrogen in the film may cause dangling bonds to be formed. The nitrogen content is desirably 0 to about 57.1%. If for example, the sputtering process is used for film formation, it is possible to use, for example, a technique to introduce nitrogen into the atmosphere or to use a target containing N such as ZrN or GeN.

Alternatively, after a ZrGeO film has been formed, nitrogen can be introduced into the film by plasma nitridation. Specifically, active nitridation seeds (nitrogen ions, nitrogen radicals, or the like) plasma excited at temperatures between the room temperature and the melting point of Ge, 938° C. can be utilized to carry out nitridation at temperatures lower than that at which thermal nitridation is carried out. If ammonia is used as a plasma nitridation introducing gas, a temperature higher than the thermal decomposition temperature of ammonia, 500° C. or higher is effective. However, in this case, hydrogen may also be introduced into the film to reduce the oxide film to increase the number of Ge dangling bonds. This in turn increases fixed charges in the film, an interface level, and a hot electron capture level. This degradation can be avoided by adding an oxidization operation.

Alternatively, nitrogen can be introduced using radical nitridation, an ammonia process, a nitrogen oxide (NO) process, a dinitrogen oxide (N₂O) process, or the like. The ammonia process can be executed by allowing an ammonia gas to flow through a batch process type apparatus operating at temperatures between 400° C. and the melting point of Ge, 938° C., at a reduced pressure or through a load lock type sheet-fed apparatus. The nitrogen oxide process and the dinitrogen oxide process can be executed by allowing an NO gas or an N₂O gas to flow through a batch process type apparatus operating at temperatures between 400° C. and the melting point of Ge, 938° C. at a reduced pressure or through a load lock type sheet apparatus. Rapid thermal nitridation (RTN), which executes processing only for a short time but has a high temperature rise speed, is effective in increasing the concentration of nitrogen in the film.

The present invention will be described in further detail with reference to specific examples.

### EXAMPLE 1

A ZrO₂ film of Ge/(Ge+Zr)=0% was deposited by the sputtering film formation process on the Ge substrate 11 to a film thickness of about 3 nm, an element isolation insulating film 16 being already formed on the Ge substrate 11. Subsequently, a thermal treatment was executed in a nitrogen atmosphere at 500° C. for 30 minutes to form a gate insulating film 12.

A Z contrast of the TEM was used to observe the concentration distribution of Zr in the interface between the Ge substrate 11 and the gate insulating film 12. The results of the observation showed that the concentration of Zr reached the bulk value at a distance of 0.5 nm from the surface of the Ge substrate 11. Further, when the TEM was used to observe the gate insulating film 12, crystallized ZnO₂ was found in the film.

A conventional method was used to form a gate electrode 13 on the gate insulating film 12. Moreover, a source area 14 and a drain area 15 were formed on the Ge substrate 11 to obtain the MISFET shown in FIG. 11.

### EXAMPLE 2

A ZrGeO film of Ge/(Ge+Zr)=50% was deposited by the sputtering film formation process on the Ge substrate 11 to a film thickness of about 3 nm, an element isolation insulating film 16 being already formed on the Ge substrate 11. Subsequently, a thermal treatment was executed in a nitrogen atmosphere at 600° C. for 30 minutes to form a gate insulating film 12.

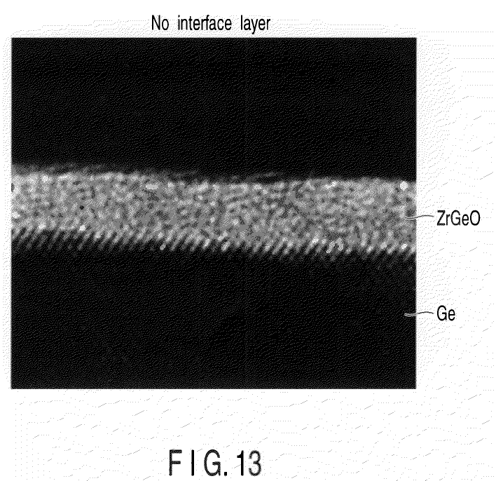

Observation was made of the concentration distribution of Zr in the interface between the Ge substrate 11 and the gate insulating film 12. The results of the observation showed that the concentration of Zr reached the bulk value at a distance of 0.5 nm from the surface of the Ge substrate 11. It was thus confirmed that no interface layer was present. Further, when the TEM was used to observe the gate insulating film 12, the gate insulating film 12 was found to be amorphous. That is, as shown in the photograph in FIG. 13, an amorphous film was able to be formed directly in contact with the Ge substrate without any interface layer.

The conventional method was used to form a gate electrode 13 on the gate insulating film 12. Moreover, a source area 14 and a drain area 15 were formed on the Ge substrate 11 to obtain the MISFET shown in FIG. 11.

### EXAMPLE 3

A ZrO₂ film was deposited by the sputtering film formation process on the Ge substrate 11 to a film thickness of about 3 nm, an element isolation insulating film 16 being already formed on the Ge substrate 11. Then, Ge ions were injected into the ZrO₂ film obtained, and a thermal treatment was then executed at 400° C. for 30 minutes to form a gate insulating film 12 consisting of a ZrGeO film. A thermal operation at about half the melting point of Ge (about 350° C.) is performed to grow Ge atoms in a solid phase using the substrate Ge as a seed crystal; the Ge atoms pass through the insulating film to reach and damage the Ge substrate and then remain as surplus Ge atoms. The Ge atoms are thus incorporated into the Ge substrate to repair the substrate damage.

Observation was made of the concentration distribution of Zr in the interface between the Ge substrate 11 and the gate insulating film 12. The results of the observation showed that the concentration of Zr reached the bulk value at a distance of 0.5 nm from the surface of the Ge substrate 11. It was thus confirmed that no interface layer was present between the Ge substrate 11 and the gate insulating film 12 and that the gate insulating film 12 was amorphous.

The conventional method was used to form a gate electrode 13 on the gate insulating film 12. Moreover, a source area 14 and a drain area 15 were formed on the Ge substrate 11 to obtain the MISFET shown in FIG. 11.

### EXAMPLE 4

A 2-nm ZrO₂ film and a 1-nm GeO₂ film were sequentially deposited by the sputtering process on the Ge substrate 11 on which an element isolation insulating film 16 had already been formed, to form a stacked film. Then, the stacked film obtained was thermally treated at 400° C. for 30 minutes to sufficiently mix the ZrO₂ film and the GeO₂ film together. Thus, a gate insulating film 12 consisting of a ZrGeO film was formed.

Observation was made of the concentration distribution of Zr in the interface between the Ge substrate 11 and the gate insulating film 12. The results of the observation showed that the concentration of Zr reached the bulk value at a distance of 0.5 nm from the surface of the Ge substrate 11. It was thus confirmed that no interface layer was present between the Ge substrate 11 and the gate insulating film 12 and that the gate insulating film 12 was amorphous.

The conventional method was used to form a gate electrode 13 on the gate insulating film 12. Moreover, a source area 14 and a drain area 15 were formed on the Ge substrate 11 to obtain the MISFET shown in FIG. 11.

### EXAMPLE 5

A process similar to the Example 2 was executed except for introduction of nitrogen into the atmosphere for the sputter film formation. Thus, a ZrGeON film was deposited on the Ge substrate 11 on which an element isolation insulating film 16 had already been formed, to form a gate insulating film 12.

Observation was made of the concentration distribution of Zr in the interface between the Ge substrate 11 and the gate insulating film 12. The results of the observation showed that the concentration of Zr reached the bulk value at a distance of 0.5 nm from the surface of the Ge substrate 11. It was thus confirmed that no interface layer was present. Further, the gate insulating film 12 was amorphous and contained about 10 atom % of nitrogen.

The conventional method was used to form a gate electrode 13 on the gate insulating film 12. Moreover, a source area 14 and a drain area 15 were formed on the Ge substrate 11 to obtain the MISFET shown in FIG. 11.

### EXAMPLE 6

A technique similar to the Example 2 was used to carry out sputter film formation and a thermal process. Thus, a gate insulating film 12 consisting of a ZrGeO film was formed on the Ge substrate 11 on which an element isolation insulating film 16 had already been formed. Plasma nitridation was used to introduce nitrogen into the ZrGeO film obtained. The plasma nitridation was carried out in a nitrogen atmosphere at the room temperature.

Observation was made of the concentration distribution of Zr in the interface between the Ge substrate 11 and the gate insulating film 12. The results of the observation showed that the concentration of Zr reached the bulk value at a distance of 0.5 nm from the surface of the Ge substrate 11. It was thus confirmed that no interface layer was present. Further, the gate insulating film 12 was amorphous and contained about 10 atom % of nitrogen.

The conventional method was used to form a gate electrode 13 on the gate insulating film 12. Moreover, a source area 14 and a drain area 15 were formed on the Ge substrate 11 to obtain the MISFET shown in FIG. 11.

### EXAMPLE 7

Thermal oxidation was used to form a tunnel oxide film 22 on the Si substrate 21 on which an element isolation insulating film 28 had already been formed. A floating gate 23 consisting SiGe and having poly Ge on its surface is deposited on the tunnel oxide film 22. Moreover, a ZrGeO film of Ge/(Ge+Zr)=50% was formed by the sputtering process to form an interpoly insulating film 24.

Observation was made of the concentration distribution of Zr in the interface between the floating gate 23 and the interpoly insulating film 24. The results of the observation showed that the concentration of Zr reached the bulk value at a distance of 1 nm from the surface of the floating gate 23. That is, an interface layer was present between the floating gate 23 and the interpoly insulating film 24. Further, the interpoly insulating film 24 was amorphous.

A control gate 25 was formed on the interpoly insulating film by the CVD process, and exposure, development, and anisotropic etching were carried out on the stacked structure obtained. Moreover, a source area 26 and a drain area 27 were formed on the Si substrate 21 to obtain the flash memory shown in FIG. 12.

### EXAMPLE 8

A technique similar to the Example 7 was executed except that the ZrGeO film subjected to sputter film formation was thermally treated at 400° C. for 30 minutes. A flash memory was thus produced.

Observation was made of the concentration distribution of Zr in the interface between the floating gate 23 and the interpoly insulating film 24. The results of the observation showed that the concentration of Zr reached the bulk value at a distance of 0.5 nm from the surface of the floating gate 23. It was thus confirmed that no interface layer was present. Further, the interpoly insulating film 24 was amorphous.

### EXAMPLE 9

A technique similar to the Example 7 was executed except that a ZrO₂ film was formed on the floating gate 23 by sputtering and was then thermally treated at 400° C. for 30 minutes to form an interpoly insulating film 24. A flash memory was thus produced.

Observation was made of the concentration distribution of Zr in the interface between the floating gate 23 and the interpoly insulating film 24. The results of the observation showed that the concentration of Zr reached the bulk value at a distance of 0.5 nm from the surface of the floating gate 23. It was thus confirmed that no interface layer was present. Further, the interpoly insulating film 24 was amorphous.

### EMBODIMENT 10

A technique similar to the Example 9 was executed except that the floating gate 23 was changed to poly Si₁₋ₓGeₓ (x is 0 to 1) and that a control gate 25 was formed on the interface in the interpoly insulating film 24 using SiGe having poly Ge. A flash memory was thus produced.

Observation was made of the concentration distribution of Zr in the interface between the control gate 25 and the interpoly insulating film 24. The results of the observation showed that the concentration of Zr reached the bulk value at a distance of 0.5 nm from the surface of the control gate 25. Thus, no interface layer was confirmed to be present. Further, the interpoly insulating film 24 was amorphous.

### EMBODIMENT 11

A technique similar to the Example 7 was executed except that the floating gate was subjected to plasma nitridation after sputter film formation and before the formation of a ZrGeO film. A flash memory was thus produced. An interface layer consisting of GeON and having a film thickness of about 1 nm was formed on the surface of the floating gate by plasma nitridation. Compared to an interface layer formed of only Ge oxide, a GeON film had excellent element characteristics in terms of leakage current. In this case, if the floating gate is SiGe, the interface layer is composed of GeSiON.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1-10. (canceled)

11. A method for manufacturing a semiconductor device comprising:
forming an insulating film area containing metal, germanium, and oxygen, on a Ge semiconductor area, the Ge semiconductor area being a Ge substrate, or a Ge on insulator; and
thermally treating the insulating film area to reduce a film thickness of a part of the insulating film area to at most 0.5 nm, the part being located between the insulating film area and the Ge semiconductor area and having metal content smaller than a bulk concentration in the insulating film area.

12. The method according to claim 11, wherein the metal contains at least one selected from a group consisting of Al, Ba, Ce, Gd, Hf, La, Mg, Pb, Pr, Sc, St, Ta, Ti, Y, and Zr.

13. The method according to claim 11, further comprising adding nitrogen to the insulating film area.

14. (canceled)

15. The method according to claim 11, wherein the insulating film area is a gate insulating film, the method further comprising forming a gate electrode formed on the gate insulating film.

16-20. (canceled)

21. A semiconductor device, comprising:
a Ge semiconductor area which is a Ge substrate or a Ge on insulator; and
an insulating film area formed in direct contact with the Ge semiconductor area and containing metal, germanium, oxygen, and nitrogen, the insulating film area being amorphous.

22. The semiconductor device according to claim 21, wherein the insulating film area is a gate insulating film, the semiconductor device further comprising a gate electrode formed on the gate insulating film.

23. A semiconductor device, comprising:
a Ge semiconductor area which is a Ge substrate, or a Ge on insulator; and
an insulating film area formed in direct contact with the Ge semiconductor area and containing metal, germanium, oxygen, and nitrogen, the metal being at least one selected from a group consisting of Al, Ba, Ce, Gd, Hf, La, Mg, Pb, Pr, Sc, St, Ta, Ti, Y, and Zr.

24. The semiconductor device according to claim 23, wherein the insulating film area is a gate insulating film, the semiconductor device further comprising a gate electrode formed on the gate insulating film.
